(19) United States
(12) Patent Application Publication
(10) Pub. No.: US 2024/0389468 A1
(43) Pub. Date: Nov. 21, 2024

(54) MRAM DEVICE WITH TRAPEZOID SHAPED ELECTRODES

(71) Applicant: INTERNATIONAL BUSINESS MACHINES CORPORATION, ARMONK, NY (US)

(72) Inventors: Oscar van der Straten, Guilderland Center, NY (US); Chih-Chao Yang, Glenmont, NY (US); Koichi Motoyama, Clifton Park, NY (US)

(21) Appl. No.: 18/317,951

(22) Filed: May 16, 2023

(51) Int. Cl. H10N 50/80; H10B 61/00; H10N 50/01; H10N 50/20

(52) U.S. Cl. CPC H10N 50/80; H10B 61/00; H10N 50/01; H10N 50/20

(57) ABSTRACT

A semiconductor device including a magnetic tunnel junction (MTJ) stack, where a cross section of a bottom electrode of the MTJ stack comprises a trapezoid profile. A semiconductor device including a lower word line and a first electrode above and connected to the lower word line, where a cross section of an electrode includes a trapezoid profile. A method including forming a bottom electrode, the bottom electrode includes a tapered side surface including a width at an upper surface of the bottom electrode less than a width at a lower surface of the bottom electrode.

### BACKGROUND

The present invention relates, generally, to the field of semiconductor manufacturing, and more particularly to fabricating a magnetic tunnel junction device with trapezoid shaped electrodes.

Magneto resistive random-access memory (“MRAM”) devices are used as non-volatile computer memory. MRAM data is stored by magnetic storage elements. The elements are formed from two ferromagnetic layers, each of which can hold a magnetic field, separated by a spin conductor layer. One of the two layers is a reference magnet, or a reference layer, set to a particular polarity, while the remaining layer's field can be changed to match that of an external field to store memory and is termed the “free magnet” or “free-layer”. This configuration is known as the magnetic tunnel junction (MTJ) and is the simplest structure for a MRAM bit of memory.

### SUMMARY

According to an embodiment of the present invention, a semiconductor device is provided. The semiconductor device including a magnetic tunnel junction (MTJ) stack, where a cross section of a bottom electrode of the MTJ stack comprises a trapezoid profile.

According to an embodiment of the present invention, a semiconductor device is provided. The semiconductor device including a lower word line and a first electrode above and connected to the lower word line, where a cross section of an electrode includes a trapezoid profile.

According to an embodiment of the present invention, a method is provided. The method including forming a bottom electrode, the bottom electrode includes a tapered side surface including a width at an upper surface of the bottom electrode less than a width at a lower surface of the bottom electrode.

### BRIEF DESCRIPTION OF THE DRAWINGS

The following detailed description, given by way of example and not intended to limit the invention solely thereto, will best be appreciated in conjunction with the accompanying drawings, in which:

FIG. 1 illustrates a cross-sectional view of a multi-state memory cell, according to an exemplary embodiment;

FIG. 2 illustrates a cross-sectional view of the multi-state memory cell and illustrates formation of a bottom electrode layer and a hard mask, according to an exemplary embodiment;

FIG. 3 illustrates a cross-sectional view of the multi-state memory cell and illustrates patterning of a bottom electrode from the bottom electrode layer and removal of the hard mask, according to an exemplary embodiment;

FIG. 4 illustrates a cross-sectional view of the multi-state memory cell and illustrates formation of an inter-layer dielectric, a reference layer, a tunneling barrier, a free layer and a hard mask, according to an exemplary embodiment;

FIG. 5 illustrates a cross-sectional view of the multi-state memory cell and illustrates patterning of the reference layer, the tunneling barrier and the free layer and removal of the hard mask, according to an exemplary embodiment;

FIG. 6 illustrates a cross-sectional view of the multi-state memory cell and illustrates formation of an encapsulation layer, according to an exemplary embodiment;

FIG. 7 illustrates a cross-sectional view of the multi-state memory cell and illustrates removal of portions of the encapsulation layer, according to an exemplary embodiment;

FIG. 8 illustrates a cross-sectional view of the multi-state memory cell and illustrates formation of an inter-layer dielectric, a top electrode layer and a hard mask, according to an exemplary embodiment;

FIG. 9 illustrates a cross-sectional view of the multi-state memory cell and illustrates patterning of a top electrode from the top electrode layer and removal of the hard mask according to an exemplary embodiment; and

FIG. 10 illustrates a cross-sectional view of the multi-state memory cell and illustrates formation of an inter-layer dielectric and an upper metal wire, according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiment set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As stated above, magneto resistive random-access memory (hereinafter “MRAM”) devices are a non-volatile computer memory technology. MRAM data is stored by magnetic storage elements. The elements are formed from two ferromagnetic layers, each of which can hold a magnetic field, separated by a spin conductor layer. One of the two layers is a reference magnet, or a reference layer, set to a particular polarity, while the remaining layer's field can be changed to match that of an external field to store memory and is termed the “free magnet” or “free-layer”. The magnetic reference layer may be referred to as a reference layer, and the remaining layer may be referred to as a free layer. This configuration is known as the magnetic tunnel junction (hereinafter “MTJ”) and is the simplest structure for a MRAM bit of memory.

A memory device is built from a grid of such memory cells or bits. In some configurations of MRAM, such as the type further discussed herein, the magnetization of the magnetic reference layer is fixed in one direction (up or down), and the direction of the magnetic free layer can be switched by external forces, such as an external magnetic field or a spin-transfer torque generating charge current. A smaller current (of either polarity) can be used to read resistance of the device, which depends on relative orientations of the magnetizations of the magnetic free layer and the magnetic reference layer. The resistance is typically higher which the magnetizations are anti-parallel and lower when they are parallel, though this can be reversed, depending on materials used in fabrication of the MRAM.

The MRAM stack layers may be conformally formed using known techniques. In formation of the MTJ stacks layers, the reference layer is formed on a dielectric and a bottom electrode. The tunneling barrier layer is formed on the reference layer. In an embodiment, the tunneling barrier layer is a barrier, such as a thin insulating layer or electric potential, between two electrically conducting materials. Electrons (or quasiparticles) pass through the tunneling barrier layer by the process of quantum tunneling. In certain embodiments, the tunneling barrier layer includes at least one sublayer composed of magnesium oxide (MgO). It should be appreciated that materials other than MgO can be used to form the tunneling barrier layer. The free layer is a magnetic free layer that is adjacent to tunneling barrier layer and opposite the reference layer. The free layer has a magnetic moment or magnetization that can be flipped. It should also be appreciated that the MTJ stack layers may include additional layers, omit certain layers, and each of the layers may include any number of sublayers. Moreover, the composition of layers and/or sublayers may be different between the different MRAM stacks.

For high performance MRAM devices based on perpendicular magnetic tunnel junction (MTJ) structures, well-defined interfaces and interface control are essential. MTJ structures typically include a cobalt (Co) based synthetic anti-ferromagnet (SAF), a CoFeB-based reference layer, a MgO-based tunnel barrier, a CoFeB-based free layer, and cap layers containing e.g. tantalum (Ta) and/or ruthenium (Ru). Embedded MTJ structures are usually formed by subtractive patterning of blanket MTJ stacks into pillars between two metal levels.

A problem when forming an embedded MTJ structures is an MRAM tunnel barrier short. Reactive ion etch (RIE) and ion beam etch (IBE) processing of such MTJ stacks presents a major challenge as it typically leads to shorts due to re-sputtering of thick bottom metal layers on MTJ stack sidewalls. There is a need for an embedded MTJ structure formed by methods with a reduced risk of shorts due to metal re-sputtering.

A problem when forming an inter-layer dielectric (ILD) surrounding multiple layers of an MTJ structures is an MRAM short due to gap fill issues. After MTJ stack patterning, the inter-pillar spaces are filled with an ILD to enable connection to back end of line (BEOL) wiring by a top contact level. ILD gap fill between pillars presents a significant challenge since the presence of voids in the ILD between the pillars can lead to shorts. The shorts are formed when a gap in the ILD is filled with a conductive material when a subsequent top contact is formed, leaded to a short between adjacent top contacts of adjacent MTJ pillars. There is a need for an embedded MTJ structure formed by methods with a reduced risk of shorts due to gap fill issues.

In this invention, trapezoid shaped bottom electrodes and top electrodes help prevent shorts due to metal re-sputtering and help prevent shorts due to gap fill issues. The trapezoid shaped electrodes extend as scalability of MRAM/memory elements due to a void-free ILD gap fill between MRAM pillars and improvement of embedded MRAM performance due to reduced top contact shorts.

In an embodiment, the bottom electrode and the top electrode have a trapezoid shape, with a wider lower horizontal surface than an upper horizontal surface. The trapezoid shape helps to prevent metal re-sputtering. Inter-pillar spaces are filled with multiple ILD layers. A first ILD surrounds the bottom electrode. A second ILD surrounds an encapsulation layer which surrounds the reference layer, the tunneling barrier and the free layer. A third ILD surrounds the top electrode. Each of these ILD layers has a low aspect ratio reducing a gap fill concern.

The present invention relates to fabricating a MTJ device with trapezoid shaped electrodes.

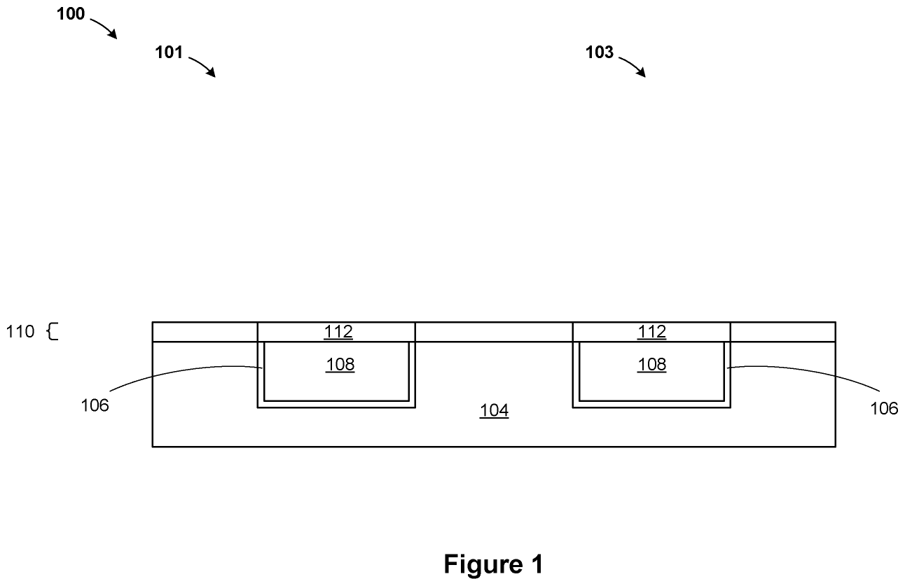

Referring now to FIG. 1, a semiconductor structure 100 (hereinafter “structure”) at an intermediate stage of fabrication is shown according to an exemplary embodiment. FIG. 1 is a cross-sectional view of the structure 100. The structure 100 may be formed or provided. The structure 100 may include a cell 101 and a cell 103. The cells 101, 103, each includes, for example, an inter-layer dielectric (hereinafter “ILD”) 104, a liner 106, a lower metal wire 108, a dielectric cap 110, and a metal cap 112.

The structure 100 may include several back end of line (“BEOL”) layers. In general, the back end of line (BEOL) is the second portion of integrated circuit fabrication where the individual devices (transistors, capacitors, resistors, etc.) are interconnected with wiring on the wafer.

The ILD 104 may be formed by depositing or growing a dielectric material on the BEOL layers, followed by a chemical mechanical polishing (CMP) or etch steps. The ILD 104 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the ILD 104 may include one or more layers. In an embodiment, the ILD 104 may include any dielectric material such as silicon oxide (SiOx), silicon nitride (SiNx), silicon boron carbonitride (SiBCN), NBLoK, a low-k dielectric material (with k<4.0), including but not limited to, silicon oxide, spin-on-glass, a flowable oxide, a high-density plasma oxide, borophosphosilicate glass (BPSG), or any combination thereof or any other suitable dielectric material.

The lower metal wire 108 may be formed by first patterning a trench (not shown) into the ILD 104, lining the trench with the liner 106, and filling the trench.

The liner 106 separates the conductive interconnect material of the lower metal wire 108 from the ILD 104. The liner 106 may be composed of, for example, tantalum nitride (TaN), tantalum (Ta), titanium (Ti), titanium nitride (TiN), or a combination thereof. The liner 106 may be deposited utilizing a conventional deposition process such as, for example, CVD, plasma enhanced chemical vapor deposition (PECVD), PVD or ALD. The liner 106 may be 5 nm thick, although a thickness less than or greater than 5 nm may be acceptable. The liner 106 surrounds a lower horizontal surface and a vertical side surface of the lower metal wire 108.

In an embodiment, the lower metal wire 108 is formed from a conductive material layer which is blanket deposited on top of the structure 100, and directly on a top surface of the liner 106, filling the trench (not shown). The conductive material layer may include materials such as, for example copper (Cu), ruthenium (Ru), cobalt (Co), tungsten (W). The conductive material can be formed by for example, chemical vapor deposition (CVD), physical vapor deposition (PVD), and atomic layer deposition (ALD) or a combination thereof. The lower metal wire 108 is formed by damascene, or patterned from the conductive material layer, using known patterning and etching techniques. There may be any number of openings in the ILD 104, each filled with the liner 106 and the lower metal wire 108, on the structure 100.

A planarization process, such as, for example, chemical mechanical polishing (CMP), may be done to remove excess material from a top surface of the structure 100 such that upper horizontal surfaces of the lower metal wire 108, the liner 106 and the ILD 104 are coplanar.

In an embodiment, the lower metal wire 108 may have a thickness ranging from about 10 nm to about 100 nm, although a thickness less than 10 nm and greater than 100 nm may be acceptable.

The dielectric cap 110 may be formed as described for the ILD 104, directly on a top surface of the liner 106, the lower metal wire 108 and the ILD 104. The metal cap 112 may be formed by first patterning a second trench (not shown) into the dielectric cap 110 vertically aligned above the lower metal wire 108 and the liner 106, and filling the second trench. The dielectric cap 110 is unlikely to contain voids as the dielectric cap 110 is blanket deposited on the planarized upper surface of the lower metal wire 108 and the liner 106.

In an embodiment, the metal cap 112 is formed from a conductive material layer which is blanket deposited on top of the structure 100, and directly on a top surface of the dielectric cap 110, the liner 106, the lower metal wire 108 and the ILD 104. The conductive material layer may include materials such as, for example tantalum (Ta), ruthenium (Ru), titanium (Ti), tungsten (W). The conductive material can be formed by for example, chemical vapor deposition (CVD), physical vapor deposition (PVD), and atomic layer deposition (ALD) or a combination thereof. The metal cap 112 is formed by damascene, or patterned from the conductive material layer, using known patterning and etching techniques. Damascene is the method of BEOL interconnect formation. A material is deposited, patterned, and the resulting feature is metallized. Any metal overburden is removed by planarization.

A planarization process, such as, for example, chemical mechanical polishing (CMP), may be done to remove excess material from a top surface of the structure 100 such that upper horizontal surfaces of the metal cap 112 and the dielectric cap 110 are coplanar.

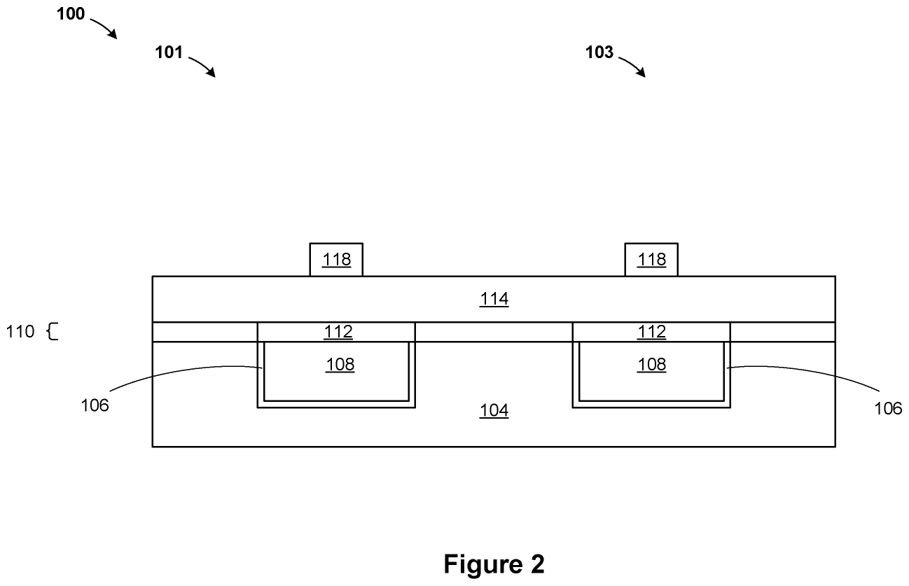

Referring now to FIG. 2, a cross-sectional view of the structure 100 is shown, according to an embodiment. A bottom electrode 114 may be formed and a hard mask 118 may be formed.

In an embodiment, the bottom electrode 114 is formed from a conductive material layer which is blanket deposited on top of the structure 100, and directly on a top surface of the metal cap 112 and the dielectric cap 110. The conductive material layer may include materials such as, for example, tantalum nitride (TaN), tantalum (Ta), titanium (Ti), titanium nitride (TiN). The conductive material layer may be deposited using typical deposition techniques, for example, physical vapor deposition, atomic layer deposition, molecular layer deposition, and chemical vapor deposition.

The hard mask 118 may formed on the structure 100 and patterned, directly on an upper horizontal surface of the bottom electrode 114.

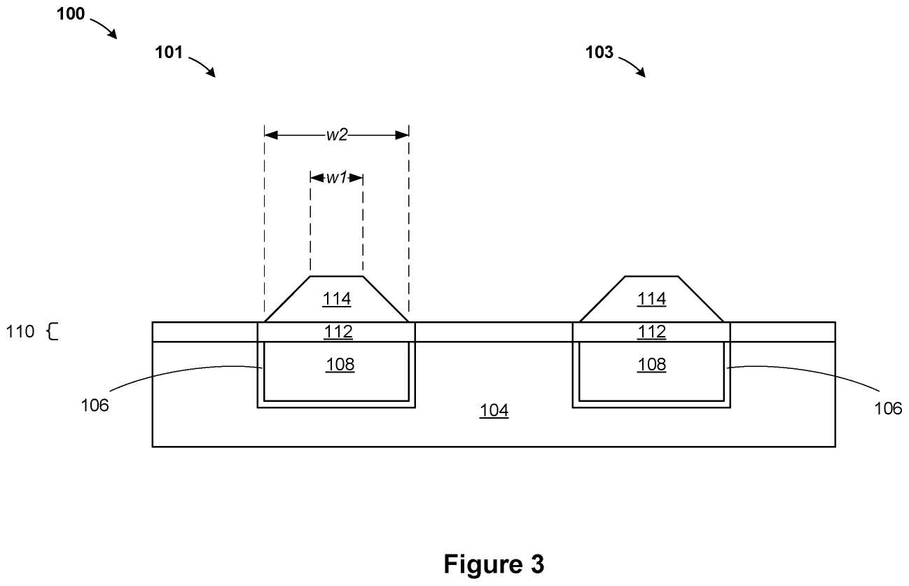

Referring now to FIG. 3, a cross-sectional view of the structure 100 is shown, according to an embodiment. Portions of the bottom electrode 114 may be removed and the hard mask 118 may be removed.

Portions of the bottom electrode 114 may be removed selective to the hard mask 118 and the dielectric cap 110. The portions of the bottom electrode 114 may be selectively removed using an anisotropic etching technique, such as, for example, reactive ion etching. The remaining portions of the bottom electrode 114 may remain vertically aligned above the metal cap 112 and the lower metal wire 108, in both of the cells 101, 103. In an embodiment, the bottom electrode 114 may have a thickness ranging from about 10 nm to about 100 nm, although a thickness less than 10 nm and greater than 100 nm may be acceptable. The bottom electrode 114 may have a tapered side surface, with a width of the bottom electrode 114 at a lower horizontal surface closer to the lower metal wire 108, w2, larger than a width at an upper horizontal surface of the bottom electrode 114, w1. Vertical sidewalls of the bottom electrode 114 may have a sidewall angle which may range between 10 and 50 degrees in an embodiment. The bottom electrode 114 may be referred to as having a trapezoid shape.

The hard mask 118 may be removed using known techniques.

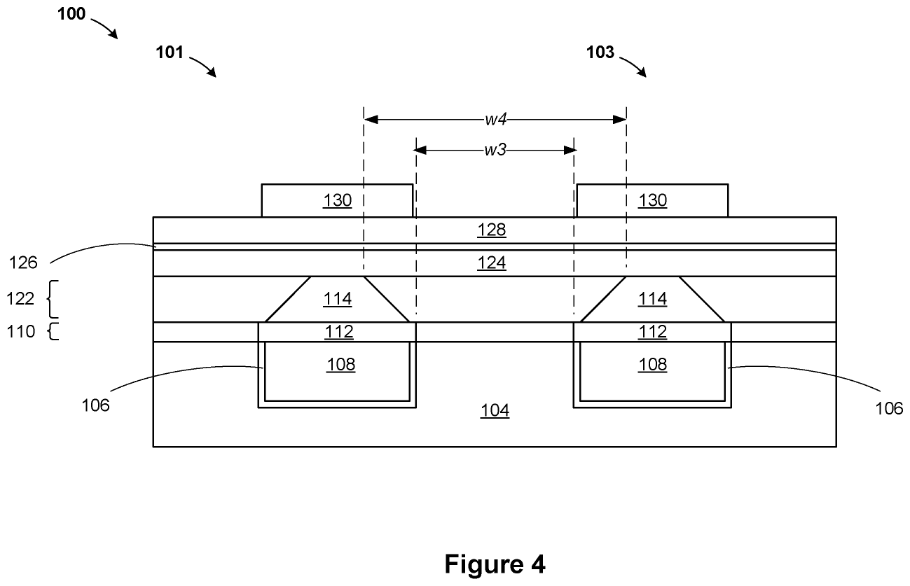

Referring now to FIG. 4, a cross-sectional view of the structure 100 is shown, according to an embodiment. An inter-layer dielectric (hereinafter “ILD”) 122, a reference layer 124, a tunneling barrier 126, a free layer 128 and a hard mask 130 may be formed.

The ILD 122 may be formed as described for the ILD 104, directly on upper horizontal surfaces and vertical side surfaces of the bottom electrode 114 and upper horizontal surfaces of the dielectric cap 110.

There is no gap fill concern when forming the ILD 122 due to the low aspect ratio of filling openings between the bottom electrode 144, due to the outward slant of vertical side surfaces of the bottom electrode 114. The ILD 122 is unlikely to contain voids as the ILD 122 is blanket deposited on the structure 100 and fills openings between adjacent bottom electrodes 144, between adjacent cells 101, 103. This is less likely to contain voids than forming an inter-layer dielectric surrounding multiple layers of the cell 101, 103. Additionally, while forming the ILD 122, the ILD 122 first fills a lower width, w3, between cells 101, 103, which is smaller than an upper width, w4, between cells 101, 103, resulting in a lower likelihood of voiding.

A planarization process, such as, for example, chemical mechanical polishing (CMP), may be done to remove excess material from a top surface of the structure 100 such that upper horizontal surfaces of the bottom electrode 114 and the ILD 122 are coplanar.

The reference layer 124 may be formed conformally on the structure 100. The reference layer 124 may cover an upper horizontal surface of the ILD 122 and an upper horizontal surface of the bottom electrode 114.

The tunneling barrier 126 may be formed conformally on the structure 100, on an upper horizontal surface of the reference layer 124.

The free layer 128 may be formed conformally on the structure 100, on an upper horizontal surface of the tunneling barrier 126.

The hard mask 130 may be patterned such that portions of the hard mask 130 remain vertical aligned above the bottom electrode 114, the metal cap 112 and the lower metal wire 108, in each of the cells 101, 103.

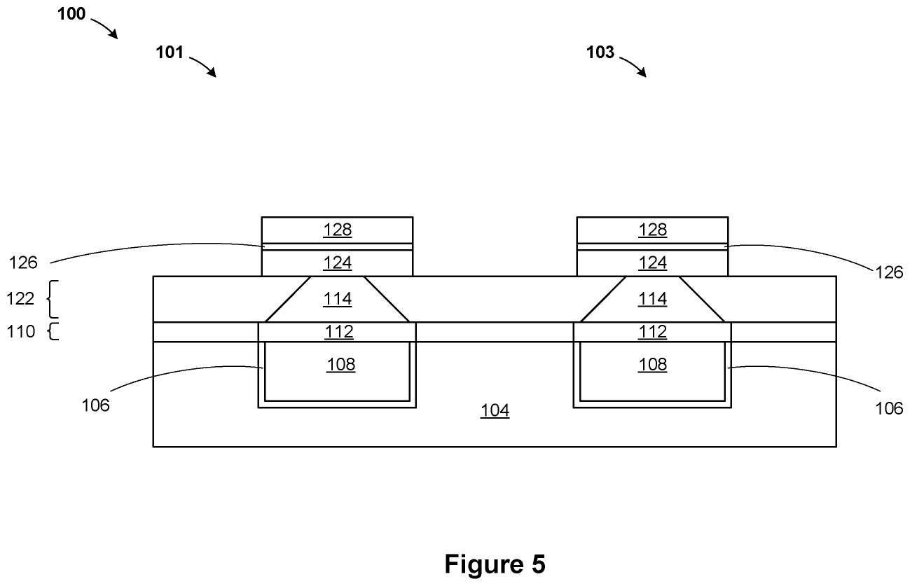

Referring now to FIG. 5, a cross-sectional view of the structure 100 is shown, according to an embodiment. Portions of the reference layer 124, portions of the tunneling barrier 126 and portions of the free layer 128 may be removed. The hard mask 130 may be removed.

The portions of the reference layer 124, the tunneling barrier 126 and the free layer 128 may be removed selective to the hard mask 130 and the ILD 122. The portions of the reference layer 124, the tunneling barrier 126 and the free layer 128 may be selectively removed using an anisotropic etching technique, such as, for example, reactive ion etching. The remaining portions of the reference layer 124, the tunneling barrier 126 and the free layer 128 may remain vertically aligned above the bottom electrode 114, the metal cap 112 and the lower metal wire 108, in each of the cells 101, 103.

There is no risk of re-sputtering of the bottom electrode 114 during the MTJ stack patterning as the bottom electrode 114 is not exposed while removing the portions of the reference layer 124, the tunneling barrier 126 and the free layer 128.

The hard mask 130 may be removed using known techniques.

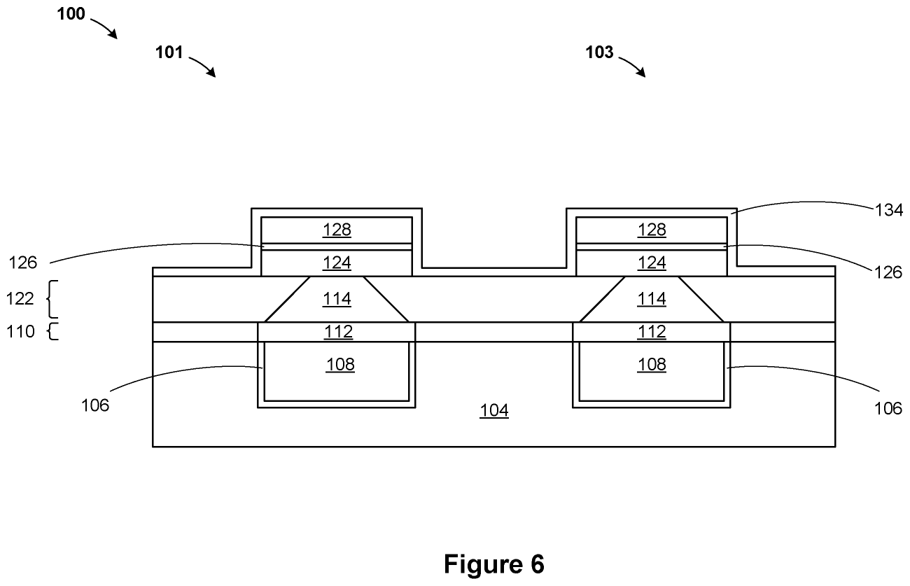

Referring now to FIG. 6, a cross-sectional view of the structure 100 is shown, according to an embodiment. An encapsulation layer 134 may be formed.

The encapsulation layer 134 may be conformally formed on the structure 100, on an upper horizontal surface of the ILD 122, on an upper horizontal surface and vertical side surfaces of the free layer 128 and on vertical side surfaces of the tunneling barrier 126 and the reference layer 124. The encapsulation layer 134 may include materials such as, for example, any dielectric material such as silicon nitride (SiN) and silicon nitride carbon (SiNC) and may include a single layer or may include multiple layers of dielectric material. In an alternate embodiment, the encapsulation layer 134 may include silicon aluminum nitride (SiAlN). The encapsulation layer 134 may be deposited using typical deposition techniques, for example, physical vapor deposition, atomic layer deposition, molecular layer deposition, and chemical vapor deposition. The encapsulation layer 134 may have a thickness between 3 nm and 30 nm, although thickness greater than 30 nm or less than 3 nm are acceptable.

The encapsulation layer 134 helps to protect the reference layer 124, the tunneling barrier 126 and the free layer 128, from being damaged or oxidized during subsequent ILD materials deposition.

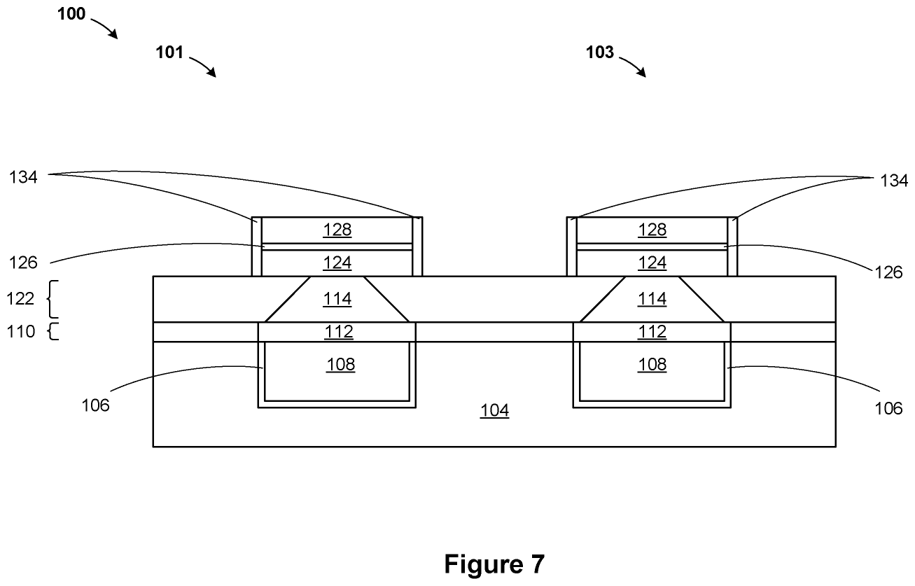

Referring now to FIG. 7, a cross-sectional view of the structure 100 is shown, according to an embodiment. Portions of the encapsulation layer 134 may be removed.

The portions of the encapsulation layer 134 may be selectively removed using a directional etching technique, such as, for example, reactive ion etching. The remaining portions of the encapsulation layer 134 may remain vertically aligned directly adjacent to the reference layer 124, the tunneling barrier 126 and the free layer 128, in both the cells 101, 103. The encapsulation layer 134 may be removed from upper horizontal surfaces of the free layer 128 and the ILD 122.

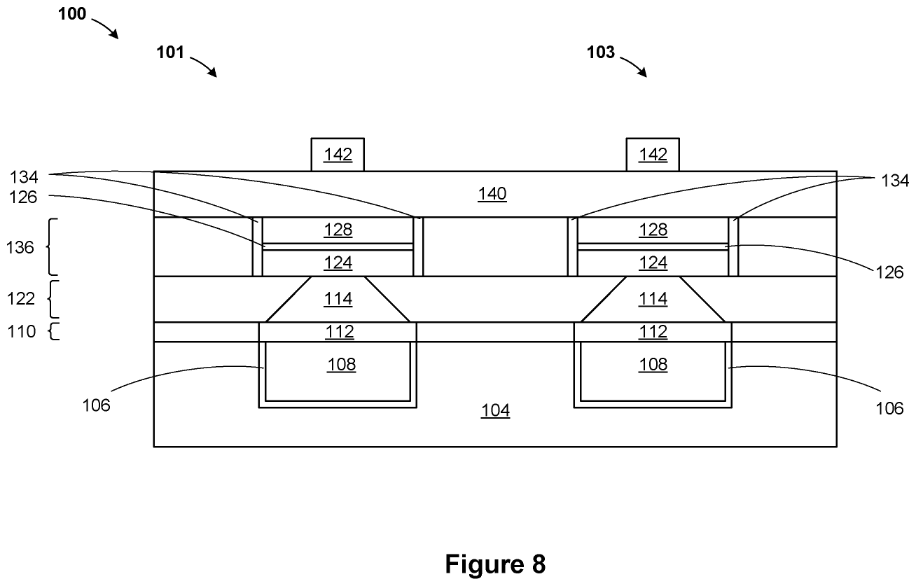

Referring now to FIG. 8, a cross-sectional view of the structure 100 is shown, according to an embodiment. An inter-layer dielectric (hereinafter “ILD”) 136 may be formed. A top electrode 140 may be formed. A hard mask 142 may be formed.

The ILD 136 may be formed as described for the ILD 104, conformally on the structure 100, covering upper horizontal surfaces of the encapsulation layer 134, the free layer 128 and the ILD 122, and vertical side surfaces of the encapsulation layer 134. The ILD 136 is unlikely to contain voids as the ILD 136 is blanket deposited on the structure 100 and fills openings between adjacent reference layers 124, tunneling barriers 126 and free layers 128 and the encapsulation layer 134 between cells 101, 103. This is less likely to contain voids than forming an inter-layer dielectric surrounding multiple layers of the cell 101, 103, for example if the multiple layers included the bottom electrode 114.

A planarization process, such as, for example, chemical mechanical polishing (CMP), may be done to remove excess material from a top surface of the structure 100 such that upper horizontal surfaces of the ILD 136, the free layer 128 and the encapsulation layer 134 are coplanar.

The top electrode 140 is formed from a conductive material layer which is blanket deposited on top of the structure 100, and directly on upper surfaces of the free layer 128, the encapsulation layer 134 and the ILD 136. The conductive material layer may include materials such as, for example, tantalum nitride (TaN), tantalum (Ta), titanium (Ti), titanium nitride (TiN). The conductive material layer may be deposited using typical deposition techniques, for example, physical vapor deposition, atomic layer deposition, molecular layer deposition, and chemical vapor deposition.

The hard mask 142 may be patterned such that portions of the hard mask 142 remain vertically aligned above the free layer 128, the tunneling barrier 126, the reference layer 124, the bottom electrode 114, the metal cap 112 and the lower metal wire 108, in each of the cells 101, 103.

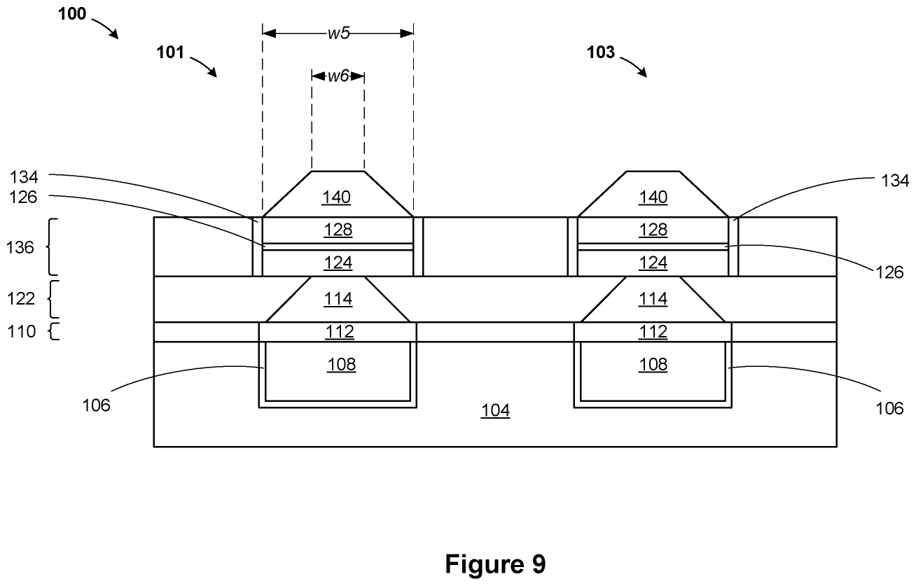

Referring now to FIG. 9, a cross-sectional view of the structure 100 is shown, according to an embodiment. Portions of the top electrode 140 may be removed. The hard mask 142 may be removed.

Portions of the top electrode 140 may be removed selective to the hard mask 142 and the ILD 136. The portions of the top electrode 140 may be selectively removed using an anisotropic etching technique, such as, for example, reactive ion etching. The remaining portions of the top electrode 140 may remain vertically aligned above the free layer 128, the tunneling barrier 126, the reference layer 124, the bottom electrode 114, the metal cap 112 and the lower metal wire 108, in both of the cells 101, 103. In an embodiment, the top electrode 140 may have a thickness ranging from about 10 nm to about 100 nm, although a thickness less than 10 nm and greater than 100 nm may be acceptable. The top electrode 140 may have a tapered side surface, with a width of the top electrode 140 at a lower horizontal surface closer to the lower metal wire 108, w5, larger than a width at an upper horizontal surface of the top electrode 140, w6. Vertical sidewalls of the top electrode 140 may have a sidewall angle which may range between 10 and 50 degrees in an embodiment. The top electrode 140 may be referred to as having a trapezoid shape.

The hard mask 142 may be removed using known techniques.

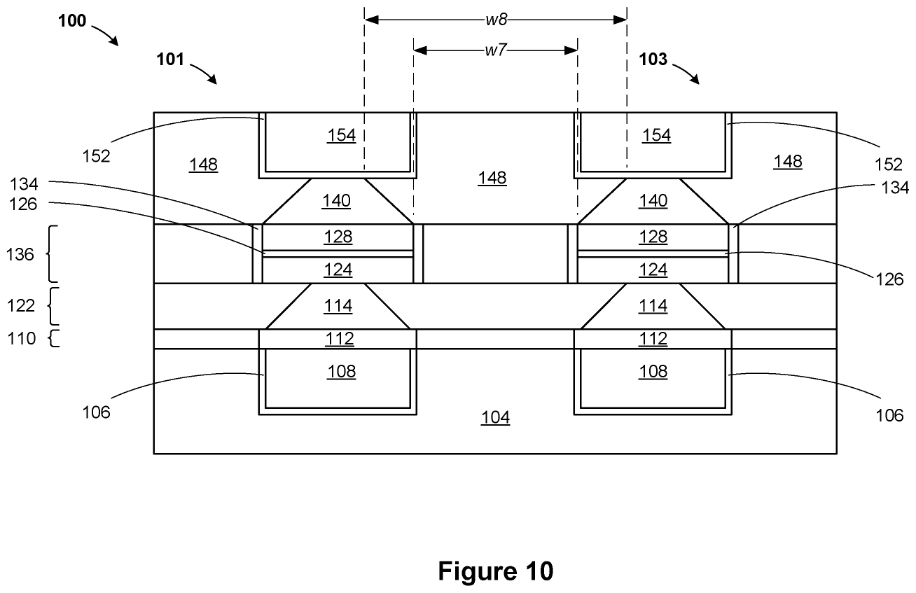

Referring now to FIG. 10, a cross-sectional view of the structure 100 is shown, according to an embodiment. An inter-layer dielectric (hereinafter “ILD”) 148 may be formed. A liner 152 may be formed. An upper metal wire 154 may be formed.

The ILD 148 may be formed as described for the ILD 104, conformally on the structure 100, covering upper horizontal surfaces of the top electrode 140, the encapsulation layer 134 and the ILD 136, and vertical side surfaces of the top electrode 140.

The ILD 148 is unlikely to contain voids as the ILD 148 is blanket deposited on the structure 100 and fills openings between adjacent top electrodes 140, between adjacent cells 101, 103. This is less likely to contain voids than forming an inter-layer dielectric surrounding multiple layers of the cell 101, 103. Additionally, while forming the ILD 148, the ILD 148 first fills a lower width, w7, between cells 101, 103, which is smaller than an upper width, w8, between cells 101, 103, resulting in a lower likelihood of voiding.

The upper metal wire 154 may be formed by first patterning a trench (not shown) into the ILD 148, lining the trench with the liner 152, and filling the trench.

The liner 152 separates the conductive interconnect material of the upper metal wire 154 from the ILD 148. The liner 152 may be formed as described for the liner 106. The liner 152 surrounds a lower horizontal surface and a vertical side surface of the upper metal wire 154.

The upper metal wire 154 may be formed as described for the lower metal wire 108. There may be any number of openings in the ILD 148, each lined with the liner 152 and the upper metal wire 154, on the structure 100.

A planarization process, such as, for example, chemical mechanical polishing (CMP), may be done to remove excess material from a top surface of the structure 100 such that upper horizontal surfaces of the upper metal wire 154, the liner 152 and the ILD 148 are coplanar.

The structure 100 has vertically aligned portions of the MTJ stack, including the bottom electrode 114, the reference layer 124, the tunneling barrier 126, the free layer 128 and the top electrode 140. The MTJ stack is vertically aligned between the lower metal wire 108 and the upper metal wire 154. The vertical side surfaces of the bottom electrode 114 and the top electrode 140 have each been individually formed with a tapered side surface wider at a lower surface, resulting in a trapezoid shape. The reference layer 124, the tunneling barrier 126, and the free layer 128 are surrounded by the encapsulation layer 134.

Additionally, the structure 100 has inter-layer dielectric layers formed separately, with the ILD 122 surrounding the bottom electrode 114, the ILD 136 surrounding the reference layer 124, the tunneling barrier 126 and the free layer 128, and the ILD 148 surrounding the top electrode 140. Each of the ILDs 122, 136, 148 are formed individually and have less voiding of an inter-layer dielectric formed at one time for a same total volume of ILD for the entire MTJ stack, for each cell 101, 103.

An MRAM pillar with trapezoid shaped electrodes helps to prevent shorts due to metal re-sputtering and helps to reduce ILD voiding between adjacent MTJ stacks. This helps to extend scalability of MRAM device memory elements due to void-free gap fill between MRAM pillars and improved embedded MRAM performance due to reduced top contact shorts.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a magnetic tunnel junction (MTJ) stack, wherein
a cross section of a bottom electrode of the MTJ stack comprises a trapezoid profile.

2. The semiconductor device according to claim 1, further comprising:
the MTJ stack comprises vertically aligned layers of a top electrode, a free layer, a tunneling barrier, a reference layer and the bottom electrode.

3. The semiconductor device according to claim 1, further comprising:
the bottom electrode comprises a tapered side surface comprising a width at an upper surface of the bottom electrode less than a width at a lower surface of the bottom electrode.

4. The semiconductor device according to claim 1, further comprising:
a cross section of a top electrode of the stack comprises a trapezoid profile.

5. The semiconductor device according to claim 4, further comprising:
the top electrode comprises a tapered side surface comprising a width at an upper surface of the top electrode less than a width at a lower surface of the top electrode.

6. The semiconductor device according to claim 1, further comprising:
a encapsulation layer surrounding vertical side surfaces of a free layer, a tunneling barrier and a reference layer.

7. A semiconductor device comprising:
a lower word line; and
a first electrode above and connected to the lower word line, wherein
a cross section of an electrode comprises a trapezoid profile.

8. The semiconductor device according to claim 7, further comprising:
a magnetic tunnel junction (MTJ) stack above and connected to the first electrode.

9. The semiconductor device according to claim 8, further comprising:
the MTJ stack comprises vertically aligned layers of a top electrode, a free layer, a tunneling barrier, a reference layer and the first electrode.

10. The semiconductor device according to claim 7, further comprising:
the first electrode comprises a side surface comprising a width at a middle section of the bottom electrode greater than a width at a lower surface of the first electrode, and the width at the middle section of the first electrode greater than a width at an upper surface of the first electrode.

11. The semiconductor device according to claim 8, further comprising:
a cross section of a second electrode of the stack comprises a trapezoid profile, wherein the second electrode is above and connected to the MTJ stack.

12. The semiconductor device according to claim 11, further comprising:
the second electrode comprises a side surface comprising a width at a middle section of the second electrode greater than a width at a lower surface of the second electrode, and the width at the middle section of the second electrode greater than a width at an upper surface of the second electrode.

13. The semiconductor device according to claim 9, further comprising:
an encapsulation layer surrounding vertical side surfaces of the free layer, the tunneling barrier and the reference layer.

14. A method comprising:
forming a bottom electrode, the bottom electrode comprises a tapered side surface comprising a width at an upper surface of the bottom electrode less than a width at a lower surface of the bottom electrode.

15. The method according to claim 14, further comprising:
forming a first inter-layer dielectric surrounding the bottom electrode.

16. The method according to claim 14, further comprising:
forming a tunneling barrier, a free layer and a top electrode, the top electrode vertically aligned above the bottom electrode.

17. The method according to claim 16, further comprising:
forming an encapsulation layer surrounding vertical side surfaces of the free layer, a tunneling barrier and a reference layer.

18. The method according to claim 17, further comprising:
forming a second inter-layer dielectric surrounding the encapsulation layer.

19. The method according to claim 16, further comprising:
forming a top electrode vertically aligned above the free layer, the tunneling barrier, the reference layer and the bottom electrode, the top electrode comprises a tapered side surface comprising a width at an upper surface of the top electrode less than a width at a lower surface of the top electrode.

20. The method according to claim 19, further comprising:
forming a third inter-layer dielectric surrounding the top electrode.
